(19) United States
(12) Patent Application Publication
(10) Pub. No.: US 2016/0070162 A1
(43) Pub. Date: Mar. 10, 2016

(54) OPTICAL MASK AND METHOD OF MANUFACTURING THE OPTICAL MASK

(71) Applicant: Samsung Display Co., Ltd., Yongin-city (KR)

(72) Inventor: Young Gil KWON, Suwon-si (KR)

(21) Appl. No.: 14/668,208

(22) Filed: Mar. 25, 2015

(30) Foreign Application Priority Data
Sep. 4, 2014 (KR) 10-2014-0117796

(51) Int. Cl. G03F 1/50; G03F 1/76

(52) U.S. Cl. CPC G03F 1/50; G03F 1/76

(57) ABSTRACT

An optical mask, including: a photothermal conversion layer configured to convert optical energy into thermal energy; and an adiabatic pattern layer disposed on the photothermal conversion layer, wherein the photothermal conversion layer includes a thermal acid generator configured to generate an acid in response to the thermal energy.

### CROSS-REFERENCE TO RELATED APPLICATION

This application claims priority from and the benefit of Korean Patent Application No. 10-2014-0117796, filed on Sep. 4, 2014, which is hereby incorporated by reference for all purposes as if fully set forth herein.

### BACKGROUND

1. Field

Exemplary embodiments relate to an optical mask and a method of manufacturing the optical mask, and more particularly, to an optical mask including a bank with a thermal acid generator and a method of manufacturing the optical mask.

2. Discussion of the Background

An organic electroluminescence (EL) device generally includes an anode electrode, a cathode electrode and organic layers interposed between the anode electrode and the cathode electrode. The organic layers may include at least a light-emitting layer (EML), and may also include a hole injection layer (HIL), a hole transport layer (HTL), an electron transport layer (ETL), and an electron injection layer (EIL). The organic EL device may be classified as a high molecular organic EL device and a low molecular organic EL device according to materials used in the organic layers.

To realize a full-color organic EL device, the EML may be patterned. More specifically, if the organic EL device is a low molecular organic EL device, the EML may be patterned by using a fine metal mask. If the organic EL device is a high molecular organic EL device, the EML may be patterned by an inkjet printing method or a laser induced thermal imaging (LITI) method.

The LITI method has many advantages, including finely patterning the organic layers and using a dry etching method rather than a wet etching method, unlike the inkjet printing method.

The patterning of a high molecular organic layer by the LITI method requires at least a light source, an organic EL device substrate, i.e., a device substrate, and a donor substrate. The donor substrate includes a base film and a transfer layer including a photothermal conversion layer and an organic film.

The photothermal conversion layer of the donor substrate absorbs light emitted from the light source, and converts it into thermal energy. The organic film of the transfer layer is then transferred onto the device substrate by the thermal energy. In this manner, an organic layer formed on the donor substrate may be patterned onto the device substrate.

### SUMMARY

Exemplary embodiments provide an optical mask to improve the operability of the manufacture of an optical mask and lower the manufacturing cost of an optical mask.

Additional features will be set forth in the description which follows, and in part will be apparent from the description, or may be learned by practice of the invention.

An exemplary embodiment discloses an optical mask, including: a photothermal conversion layer configured to convert optical energy into thermal energy; and an adiabatic pattern layer disposed on the photothermal conversion layer, wherein the photothermal conversion layer includes a thermal acid generator configured to generate an acid in response to the thermal energy.

An exemplary embodiment discloses a method of manufacturing an optical mask, including: forming a photothermal conversion layer on a transmissive substrate, the transmissive substrate including first regions and a second region; applying a photoresist composition on the photothermal conversion layer to form a photoresist composition layer on the photothermal conversion layer, the photoresist composition including a thermal acid generator; selectively exposing the photoresist composition layer to light radiated to the first regions of the transmissive substrate; and developing the photoresist composition layer in the second region of the transmissive substrate.

An exemplary embodiment discloses a method of manufacturing an optical mask, including: forming a reflective pattern layer on a transmissive substrate, the reflective pattern layer including: reflective portions configured to reflect applied light; and a transmissive portion configured to transmit applied light; forming a photothermal conversion layer on the reflective pattern layer; applying a photoresist composition on the photothermal conversion layer to form a photoresist composition layer on the photothermal conversion layer, the photoresist composition including a thermal acid generator; radiating light on the transmissive substrate; and developing a portion of the photoresist composition layer corresponding to the transmissive portion of the reflective pattern layer to form a patterned photoresist composition layer.

According to the exemplary embodiments, a photothermal conversion layer converts light applied thereto into thermal energy, and a thermal acid generator generates an acid in response to the thermal energy. Since the acid causes a cross-linking reaction or an elimination reaction for a photoresist composition in areas where light is applied, an adiabatic pattern layer can be formed at a lower compared to using lithography. Also, since Exemplary embodiments are free from additional masks, the operability of in manufacturing an optical mask can be improved, and the manufacturing cost of an optical mask can be reduced.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIGS. 1, 2, 3, 4, 5, and 6 are cross-sectional views illustrating a method of fabricating an optical mask, according to an exemplary embodiment.

FIGS. 7, 8, 9, 10, 11, and 12 are cross-sectional views illustrating a method of fabricating an optical mask, according to an exemplary embodiment.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element or layer is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

As used herein, the term “and/or” includes any and all combinations of one or more of the associated listed items. It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

It will be understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof

Exemplary embodiments will hereinafter be described with reference to the accompanying drawings.

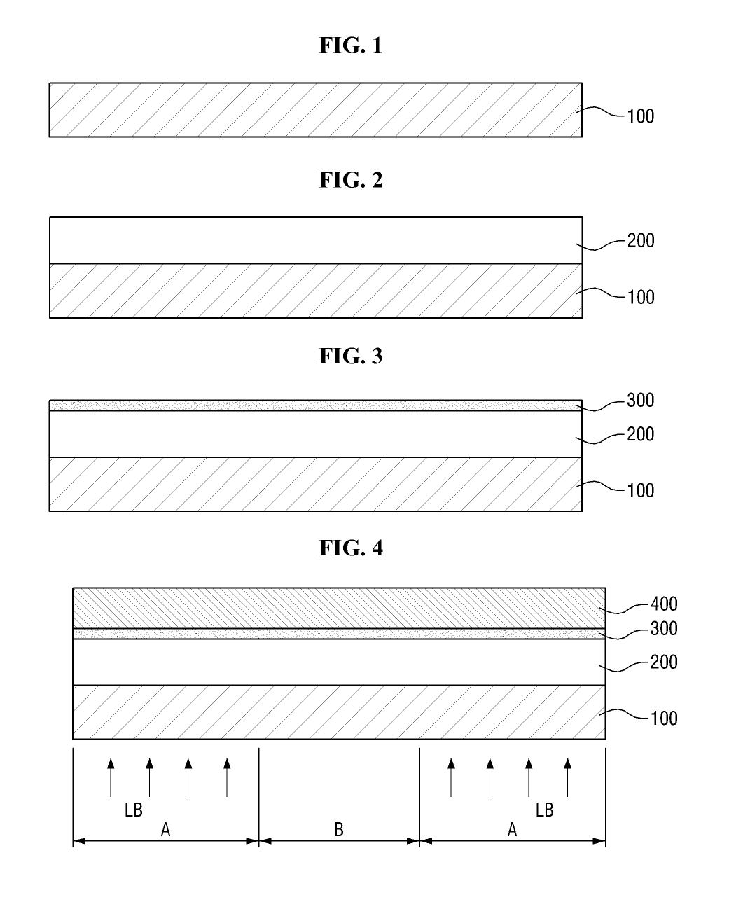

FIGS. 1, 2, 3, 4, 5, and 6 are cross-sectional views illustrating a method of fabricating an optical mask, according to an exemplary embodiment.

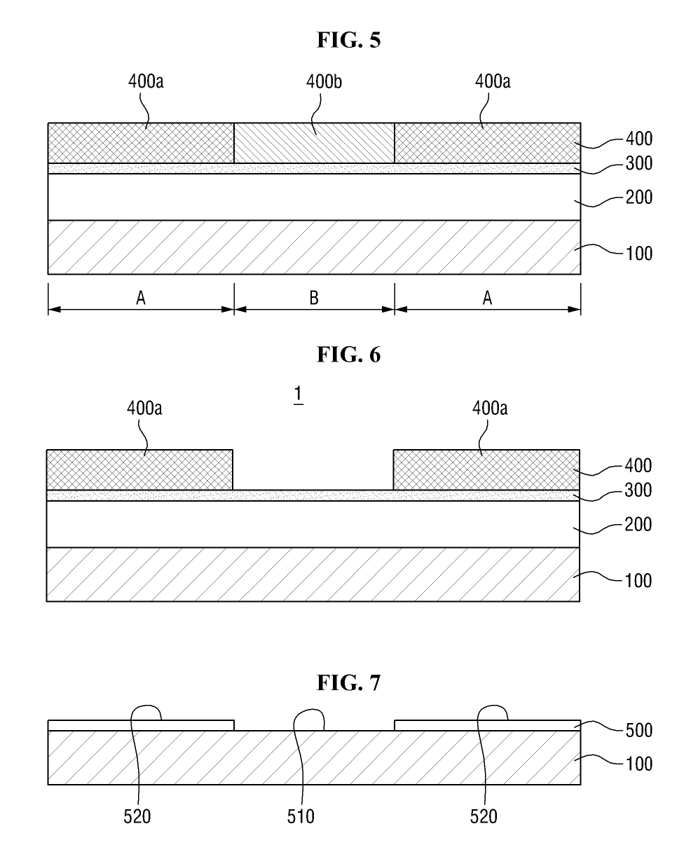

An optical mask 1 may be manufactured by the method of fabricating an optical mask, according to an exemplary embodiment. FIG. 1 illustrates a step of preparing a transmissive substrate 100. FIG. 2 illustrates a step of forming a first adiabatic layer 200 on the transmissive substrate 100. FIG. 3 illustrates a step of forming a photothermal conversion layer 300 on the first adiabatic layer 200. FIG. 4 illustrates a step of forming a second adiabatic layer 400 on the photothermal conversion layer 300 and selectively applying laser beams LB to first regions A on the transmissive substrate 100. FIG. 5 illustrates a step of forming cross-linked portions 400a and non-cross-linked portion 400b. The cross-linked portions 400a is formed where the cross-linked bond of polymers occurs in first parts of the second adiabatic layer 400 overlapping the first regions A. The non-cross-linked portion 400b is formed where the cross-linked bond of polymers does not occur in a second part of the second adiabatic layer 400 corresponding to a second region B where laser beams LB are not applied. FIG. 6 illustrates a step of forming an adiabatic pattern layer by developing the non-cross-linked portion 400b. The adiabatic pattern layer may be formed by patterning the second adiabatic layer 400 into the cross-linked portions 400a and an opening disposed between the cross-linked portions 400a, wherein the photothermal conversion layer 300 is exposed through the opening.

The transmissive substrate 100 may be a substrate capable of transmitting light, such as lamp light and/or laser beams, therethrough. The transmissive substrate 100 may be implemented as, but is not limited to, a glass substrate, a quartz substrate, and/or a synthetic resin substrate formed of at least one of following transparent polymer materials including polyester, polyacryl, polyepoxy, polyethylene, polystyrene, and/or polyethylene terephthalate. The light transmitted through the transmissive substrate 100 and the first adiabatic layer 200, may reach the photothermal conversion layer 300.

The first adiabatic layer 200 may reduce the diffusion of thermal energy generated by the photothermal conversion layer 300. More specifically, the thermal diffusion of the thermal energy generated by the photothermal conversion layer 300 may be reduced by the first adiabatic layer 200. The first adiabatic layer 200 may be formed of a material with high light transmittance and low thermal conductance. The first thermal layer 200 may be formed of a material having a thermal conductance lower than that of the photothermal conversion layer 300. For example, the first adiabatic layer 200 may be formed of at least one of, but is not limited to, titanium oxide, silicon oxide (SiOx), silicon oxynitride, zirconium oxide, silicon carbide, silicon nitride (SiNx) and an organic polymer. The first adiabatic layer 200 may be thicker than the photothermal conversion layer 200.

The photothermal conversion layer 300 may absorb light within an infrared-visible ray range transmitted thereto through the transmissive substrate 100, and may convert the light into thermal energy. The photothermal conversion layer 300 may be formed of a metal material with high absorptivity including at least one of, but not limited to, molybdenum (Mo), chromium (Cr), titanium (Ti), tin (Sn), tungsten (W) and an alloy thereof. In an exemplary embodiment, when laser beams with a wavelength of approximately 800 nm is radiated, the photothermal conversion layer 300 may include a metal such as Cr and/or Mo with low reflectivity and a high melting point. However, the invention is not limited to this exemplary embodiment. The photothermal conversion layer 300 may be formed by various methods, for example, sputtering, electron beam deposition, and vacuum deposition.

The second adiabatic layer 400 may include a negative photosensitive polymer composition including a thermal acid generator. The negative photosensitive polymer composition may be a resin that becomes insoluble upon being exposed to light and remains after development. There is nearly no restriction on the type of the negative photosensitive polymer composition.

For example, the negative photosensitive polymer composition may include a siloxane-based polymer and a cross-linking agent. The siloxane-based polymer is a copolymer including a silicon-oxygen backbone and a functional group that is unstable with respect to acids and/or heat. The siloxane-based polymer may include a monomer indicated by following Formula (1):

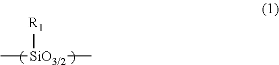

Referring to the Formula (1) above, R₁ denotes one of a cycloalkyl group, an aryl group, and/or a silyl alkyl group of a C₁-C₁₀ alkyl group with a functional group unstable with respect to acids and/or heat substituted. Examples of the functional group unstable with respect to acids and/or heat may include a —COOR₃ ester group, an —OCOOR₄ carbonate group, an —OR₅ ester group, an acetal group, and a ketal group. Examples of substituent R₃ of the —COOR₃ ester group may include t-butyl, adamantyl, norbornyl, isobornyl, 2-methyl-2-adamantyl, 2-methyl-2-isobornyl, 2-butyl-2-adamantyl, 2-propyl-2-isobornyl, 2-methyl-2-tetracyclododecenyl, and a 2-methyl-2-dihydrodicyclopentadienyl-cyclohexyl group. Examples of the —OCOOR₄ carbonate group may include a t-butoxycarbonyl group. Examples of the —OR₅ ether group may include tetrahydropyranyl ether and trialky silyl ether.

The cross-linking agent causes a cross-linking reaction triggered by acids and/or heat. For example, the cross-linking agent may include at least one of a melamine compound, a urea compound, and an uryl compound. Examples of the melamine compound may include alkoxymethyl melamine and alkylated melamine. Examples of the urea compound may include urea, alkoxymethylene urea, N-alkoxymethylene urea, ethylene urea, and tetrahydro-1,3,4,6-tetramethylimidazo[4,5-d]imidazole-2,5-(1H,3H)-dione. Examples of the uryl compound may include benzoguanamine and glycol uryl. The aforementioned examples of the melamine compound, the urea compound and the uryl compound may be used alone or together with one another, and the exemplary embodiments are not limited thereto.

Nearly any type of compound capable of generating an acid by reacting with the presence of heat may be used as the thermal acid generator, such as a sulfonate-based compound. Examples of the sulfonate-based compound are as shown in following Formulas (2), (3), (4), and (5). More specifically, the thermal acid generator may be 4,4-dimethyldiphenyliodonium hexafluorophosphate.

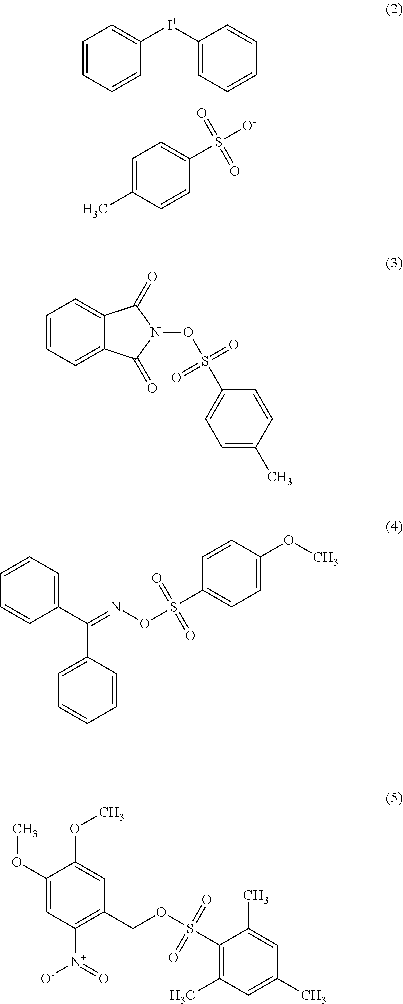 [SMILES: c1ccc([I+]c2ccccc2)cc1 ; Cc1ccc(S(=O)(=O)[O-])cc1 ; Cc1ccc(S(=O)(=O)ON2C(=O)c3ccccc3C2=O)cc1 ; COc1ccc(S(=O)(=O)ON=C(c2ccccc2)c2ccccc2)cc1 ; COc1cc(COS(=O)(=O)c2c(C)cc(C)cc2C)c([N+](=O)[O-])cc1OC]

Since the laser beams LB are radiated only to the first regions A of the transmissive substrate 100, heat may be generated only in parts of the photothermal conversion layer 300 overlapping the first regions A of the transmissive substrate 100. Due to the heat in the photothermal conversion layer 300, the thermal acid generator of the second adiabatic layer 400 may generate an acid, and the acid may work as a catalyst in a cross-linking reaction which occurs in the negative photosensitive polymer composition. The cross-linked portions 400a may be formed by curing parts of the second adiabatic layer 400 where the cross-linking reaction occurs. Laser beams LB are not radiated in the second region B of the transmissive substrate 100, and heat is not generated in the photothermal conversion layer 300. Therefore, no cross-linking reaction occurs in the negative photosensitive polymer composition in part of the second adiabatic layer 400 corresponding to the second region B of the transmissive substrate 100. Accordingly, the non-cross-linked portion 400b is formed in the part of the second adiabatic layer 400 overlapping the second region B. The cross-linked portions 400a are not removed from the photothermal conversion layer by development, whereas the non-cross-linked portion 400b is removed by development. Accordingly, the second adiabatic layer 400 is patterned into an adiabatic pattern layer with the cross-linked portions 400a arranged at regular intervals. The cross-linked portions 400a may also be referred to as barriers 400a.

The opening through which the photothermal conversion layer 300 is exposed, may be formed between the barriers 400a. A transfer layer (not illustrated) may be formed on the entire surface of the adiabatic pattern layer. That is, the transfer layer may be formed on the barriers 400a, as well as on parts of the photothermal conversion layer 300 exposed through the opening between the barriers 400a. The barriers 400a may also serve as a guide for the transfer layer when the transfer layer is sublimated by heat and deposited onto a target substrate (not illustrated).

For example, the transfer layer may include organic material layers that may be included in an organic light-emitting display device, which may include, an organic light-emitting layer (EML), a hole injection layer (HIL), a hole transport layer (HTL), an electron injection layer (EIL), and an electron transport layer (ETL), and the target substrate may be a thin-film transistor (TFT) substrate of an organic electroluminescence (EL) device. When the transfer layer (not illustrated) is sublimated onto a plurality of pixel electrodes (not illustrated) of the target layer (not illustrated), the barriers 400a may guide the sublimated transfer layer vertically onto a plurality of pixel electrodes (not illustrated) of the target substrate (not illustrated) without being diffused.

FIGS. 7, 8, 9, 10, 11, and 12 are cross-sectional views illustrating a method of fabricating an optical mask, according to an exemplary embodiment.

FIG. 7 illustrates a step of forming a reflective pattern layer 500 on a transmissive substrate 100. The reflective pattern layer 500 may include a transmissive portion 510 and reflective portions 520. The transmissive portion 510 transmits light radiated thereto from an external source (not illustrated). The reflective portions 520 are provided on either side of the transmissive portion 510 and reflect light radiated thereto from the external source (not illustrated). The reflective portions 520 of the reflective pattern layer 500 may be formed of, but is not limited to, aluminum (Al), gold (Au), silver (Ag), copper (Cu), an Al alloy, an Ag alloy, and/or indium oxide-tin oxide. The transmissive potion 510 of the reflective pattern layer 500 may overlap the opening of an adiabatic pattern layer 400, and the reflective portions 520 of the reflective pattern layer 500 may overlap the cross-linked portions 400a, respectively, of the adiabatic pattern layer 400.

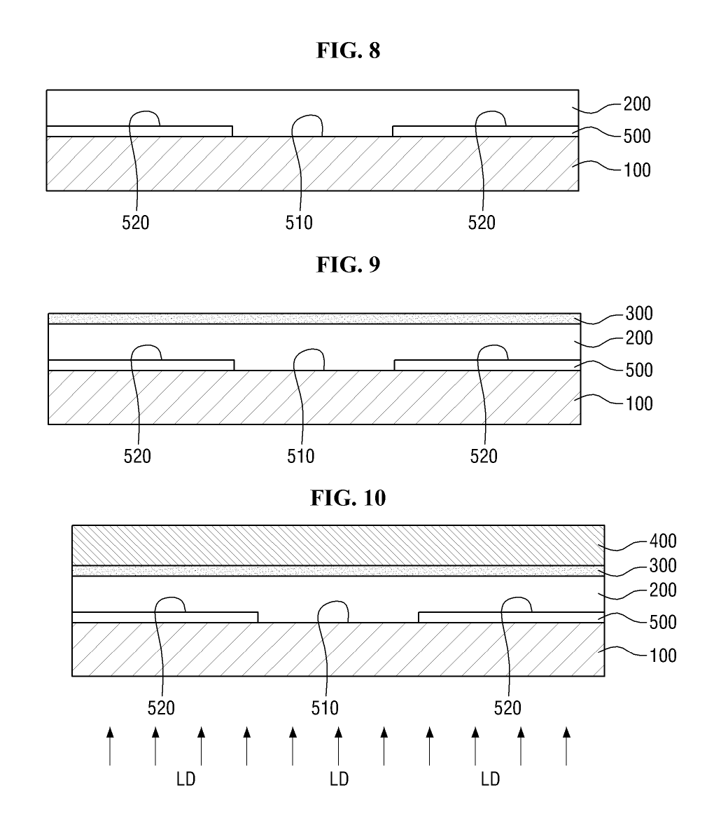

FIG. 8 illustrates a step of forming a first adiabatic layer 200 on the reflective pattern layer 500. The step illustrated in FIG. 8 is different from the step illustrated in FIG. 2, in that the first adiabatic layer 200 is formed on the surface of the reflective pattern layer 500, as well as the surface of the transmissive substrate 100. More specifically, in the exemplary embodiment illustrated in FIGS. 1, 2, 3, 4, 5, 6, and 7, no reflective pattern layer 500 is formed, and the first adiabatic layer 200 is formed directly on the surface of the transmissive substrate 100. In the exemplary embodiment of FIGS. 8, 9, 10, 11, and 12, the reflective pattern layer 500 including an opening, is formed between the transmissive substrate 100 and the first adiabatic layer 200 and therefore, the first adiabatic layer 200 is formed on the transmissive substrate 100, as well as the reflective portions 520 of the reflective pattern layer 500.

FIG. 9 illustrates a step of forming a photothermal conversion layer 300 on the first adiabatic layer 200. The step of FIG. 9 is different from the step illustrated in FIG. 3, in that the reflective pattern layer 500 is formed between the transmissive substrate 100 and the first adiabatic layer 200.

FIG. 10 illustrates a step of forming a second adiabatic layer 400 on the photothermal conversion layer 300 and applying lamp light onto the entire surface of the transmissive substrate 100. The step of FIG. 10 is different from the step illustrated in FIG. 4, in that lamp light, instead of laser light, is applied onto the entire surface of the transmissive substrate 100, rather than onto selective regions of the transmissive substrate 100.

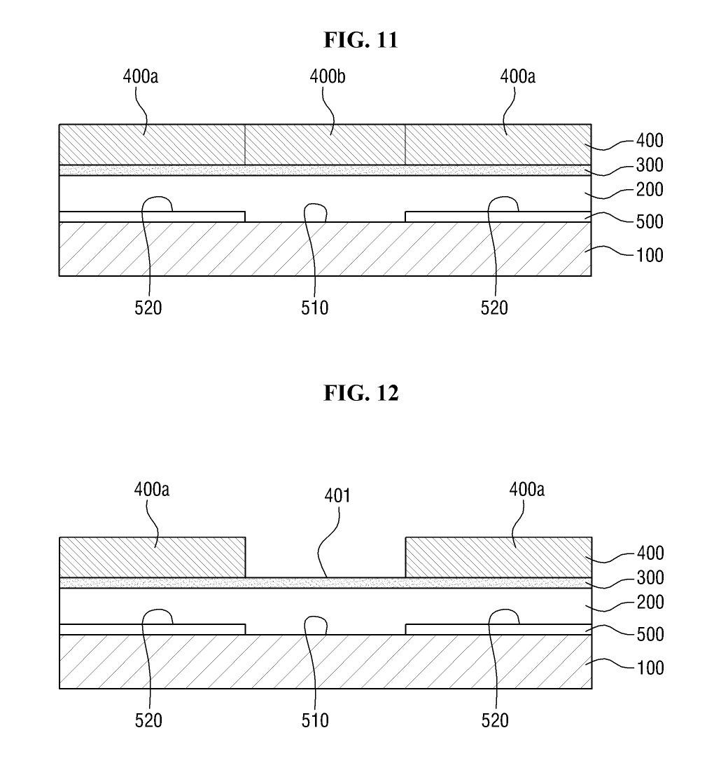

A step of FIG. 11 is different from the step illustrated in FIG. 5, in that to the lamp light radiated onto the photothermal conversion layer 300 through the transmissive portion 510 is converted into heat, and an acid generated by a thermal acid generator included in a central portion 400b of the second adiabatic layer 400 causes a protecting group elimination reaction.

The second adiabatic layer 400 includes a positive photosensitive polymer composition including a thermal acid generator. The positive photosensitive polymer composition may be a resin that may become removable by development upon being exposed to light. An acid generated by the thermal acid generator may eliminate the protecting group of a polymer resin of the positive photosensitive polymer composition, and the positive photosensitive polymer composition may become removable in areas of the second adiabatic layer 400 that are exposed to light.

For example, the positive photosensitive polymer composition may be, but is not limited to, poly[9,9′-di[4-(2-(2-tetreahydropyranyloxy)-ethoxy)phenyl]fluorine], poly[9,9′-di[4-(2-(2-tetreahydropyranyloxy)-ethyl)phenyl]fluorine], and/or poly[9,9′-di[4-(2-(2-tetreahydropyranyloxy)-ethoxy)phenyl]fluorine-co-3,4-benzothiadiazole].

More specifically, when the positive photosensitive polymer composition is poly[9,9′-di[4-(2-(2-tetreahydropyranyloxy)-ethoxy)phenyl]fluorine], the protecting group of the positive photosensitive polymer composition, e.g., dihydropyran, may be removed by the heat generated from the thermal acid generator, as indicated in Formula (6):

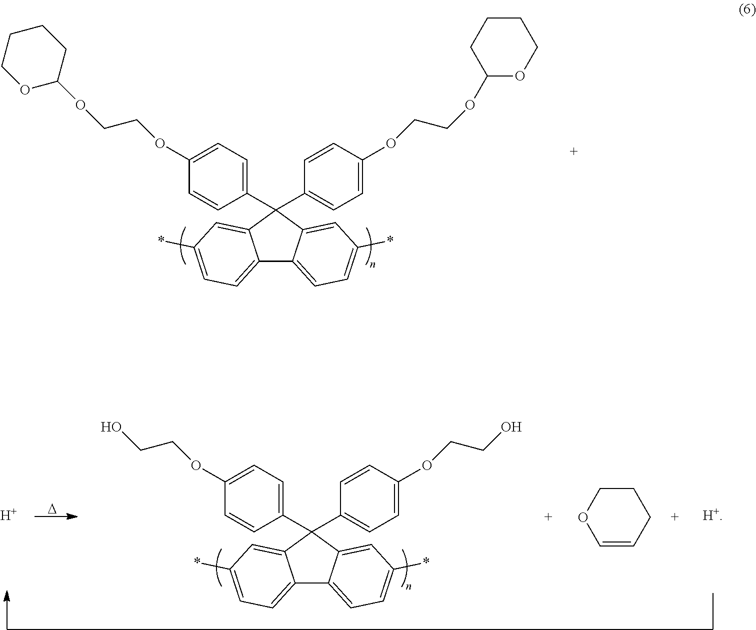

FIG. 12 illustrates a step of developing the central portion 400b of the second adiabatic layer 400 and leaving the boundary portions 400a in areas where no light is applied. The boundary portions 400a may be cured through baking, and may serve as barriers.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. An optical mask, comprising:
a photothermal conversion layer configured to convert optical energy into thermal energy; and
an adiabatic pattern layer disposed on the photothermal conversion layer,
wherein the photothermal conversion layer comprises a thermal acid generator configured to generate an acid in response to the thermal energy.

2. The optical mask of claim 1, further comprising:
a transmissive substrate,
wherein the photothermal conversion layer is interposed between the transmissive substrate and the adiabatic pattern layer.

3. The optical mask of claim 2, further comprising:
an adiabatic layer configured to reduce diffusion of the thermal energy generated by the photothermal conversion layer,
wherein the adiabatic layer is interposed between the photothermal conversion layer and the transmissive substrate.

4. The optical mask of claim 1, wherein the adiabatic pattern layer comprises:
barriers spaced apart from each other; and
openings disposed between the barriers,
wherein the openings expose the photothermal conversion layer.

5. The optical mask of claim 4, further comprising:
a reflective pattern layer overlapping the adiabatic pattern layer,
wherein the photothermal conversion layer is disposed between the reflective pattern layer and the adiabatic pattern layer.

6. The optical mask of claim 1, wherein the adiabatic pattern layer further comprises a cross-linking polymer.

7. The optical mask of claim 1, wherein the photothermal conversion layer comprise at least one of molybdenum (Mo), chromium (Cr), titanium (Ti), tin (Sn), tungsten (W), and an alloy of at least one of Mo, Cr, Ti, Sn, and W.

8. A method of manufacturing an optical mask, comprising:
forming a photothermal conversion layer on a transmissive substrate, the transmissive substrate comprising first regions and a second region;
applying a photoresist composition on the photothermal conversion layer to form a photoresist composition layer on the photothermal conversion layer, the photoresist composition comprising a thermal acid generator;
selectively exposing the photoresist composition layer to light radiated to the first regions of the transmissive substrate; and
developing the photoresist composition layer in the second region of the transmissive substrate.

9. The method of claim 8, further comprising:
forming an adiabatic layer on the transmissive substrate, the adiabatic layer being formed between the photothermal conversion layer and the transmissive substrate,
wherein the adiabatic layer is configured to reduce diffusion of thermal energy generated by the photothermal conversion layer.

10. A method of manufacturing an optical mask, comprising:
forming a reflective pattern layer on a transmissive substrate, the reflective pattern layer comprising:
reflective portions configured to reflect applied light; and
a transmissive portion configured to transmit applied light;
forming a photothermal conversion layer on the reflective pattern layer;
applying a photoresist composition on the photothermal conversion layer to form a photoresist composition layer on the photothermal conversion layer, the photoresist composition comprising a thermal acid generator;
radiating light on the transmissive substrate; and
developing a portion of the photoresist composition layer corresponding to the transmissive portion of the reflective pattern layer to form a patterned photoresist composition layer.

11. The method of claim 10, further comprising:
forming an adiabatic layer on the reflective pattern layer, the adiabatic layer being formed between the photothermal conversion layer and the reflective pattern layer,
wherein the adiabatic layer is configured to reduce diffusion of thermal energy generated by the photothermal conversion layer.

12. The method of claim 10, further comprising:
curing the photoresist pattern.

13. The method of claim 8, wherein the photothermal conversion layer is formed on an entire surface of the transmissive substrate.

14. The method of claim 8, wherein the photoresist composition is applied to an entire surface of the photoresist composition layer.

15. The method of claim 9, wherein the adiabatic layer is formed on an entire surface of the transmissive substrate.

16. The method of claim 10, wherein the photothermal conversion layer is formed on an entire surface of the reflective pattern layer.

17. The method of claim 10, wherein the photoresist composition is applied to an entire surface of the photothermal conversion layer.

18. The method of claim 10, wherein the light is radiated on an entire surface of the transmissive substrate.

19. The method of claim 11, wherein the adiabatic layer is formed on an entire surface of the reflective pattern layer.
